(19) United States
(12) Patent Application Publication
(10) Pub. No.: US 2015/0212136 A1
(43) Pub. Date: Jul. 30, 2015

(54) METHOD FOR DETERMINING OBJECT OF AIRCRAFT LIGHTNING PROTECTION ADEQUACY TEST AND METHOD FOR VERIFYING LIGHTNING PROTECTION ADEQUACY

(71) Applicant: MITSUBISHI AIRCRAFT CORPORATION, Aichi (JP)

(72) Inventors: Michizo IWAKI, Tokyo (JP); Atsuhiro IYOMASA, Tokyo (JP); Soichiro UMEMOTO, Tokyo (JP); Tomonori OKUMURA, Aichi (JP); Hideo YAMAKOSHI, Aichi (JP)

(21) Appl. No.: 14/578,648

(22) Filed: Dec. 22, 2014

(30) Foreign Application Priority Data
Jan. 27, 2014 (JP) 2014-12521

(51) Int. Cl. G01R 31/00

(52) U.S. Cl. CPC G01R 31/008; G01R 31/001

(57) ABSTRACT

A method for determining an object of a test for verifying the lightning protection adequacy of a fastening part includes: a structural pattern population generating step of generating a population of structural patterns identified by a combination of a plurality of properties of the fastening part; a section extracting step of extracting those sections which are disposed in a wet area of the aircraft where fuel or fuel vapor is present, from the sections of a fastening member, for each of the structural patterns of the population; a group setting step of setting a group of structural patterns of the same predetermined properties for each of the sections; and a representative pattern selecting step of selecting a representative pattern representative of the group from the structural patterns belonging to the same group. The structural pattern narrowed down through the steps is determined as the test object.

### BACKGROUND OF THE INVENTION

1. Field of the Invention

The present invention relates to a method for determining an object of a test for verifying the lightning protection adequacy of a part of an aircraft where members are fastened together, and to a method for verifying lightning protection adequacy.

2. Description of the Related Art

A main wing of an aircraft commonly has a hollow structure, and fuel is stored inside the main wing.

The main wing is constituted of many members and the members are fastened together with a fastener, etc. There are as many as several tens of thousands of points where the members are fastened with a fastener, etc.

Fasteners which penetrate a skin or the like and protrude to the inside of the main wing, or fasteners, etc. which are provided on a rib installed on the inside of the main wing, come into contact with fuel or fuel vapor.

Here, when the main wing is struck by lightning, the lightning current flows through the members including the skin, etc. Meanwhile, the current also flows through the fastener fastening the members together.

At this point, a high current exceeding a permissible value flows through the interface between the skin, etc. and the fastener provided in an area facing fuel or fuel vapor (wet area), and an electric discharge can occur near the interface. In addition, a rapid temperature rise due to the electric discharge can cause the fastener, the skin, etc. to be melted and scattered.

That the wet area is free of ignition sources such as arcs and sparks or melted scatters accompanying an electric discharge even in the event of lightning strike (hereinafter referred to as lightning protection adequacy) is required for preventing explosion resulting from fuel ignition due to the arcs and sparks of an electric discharge or melted scatters, etc.

Japanese Patent Laid-Open No. 2008-39775 discloses a technique related to the lightning protection adequacy. In this disclosure, a circuit board is inserted between structural members fastened with a plurality of fastening members, and a current flow through the fastening members is measured by means of a Rogowski coil formed by etching on the circuit board.

A test for verifying the lightning protection adequacy is performed by applying a high current simulating lightning to a test piece including a single or a plurality of fastened place(s), and checking that no ignition such as sparks is observed.

The lightning protection adequacy is required for all the fastening points included in the wet area.

Here, various types of fasteners, differing in terms of diameter, with/without an insulation cap, material, etc., are used for the fastening points.

Similarly, various types of structural members including the skin, etc., differing in terms of plate thickness, material, and with/without a seal on the mating surface, etc., are fastened with the fasteners.

Therefore, the types of fastening parts identified by combinations of various fasteners and various structural members are numerous, and there are, for example, as many as 1000 or more patterns.

Performing the test for verifying the lightning protection adequacy on all of 1000 or more patterns of the fastening parts creates too large a workload for the test and requires a huge amount of cost and time, hence is not practical.

Based on the above-described problem, the present invention aims to provide a method which enables efficient verification of the lightning protection adequacy of numerous patterns of fastening parts of an aircraft.

### SUMMARY OF THE INVENTION

A method for determining an object of an aircraft lightning protection adequacy test of the present invention is a method for determining an object of a test for verifying lightning protection adequacy of a fastening part which is a structure at a point where members of an aircraft are fastened together with a fastening member, wherein

the following steps are performed by using a computer having a calculation processing unit which performs calculations and a storing unit which stores information used for the calculations and activating the calculation processing unit on the basis of a computer program:
a population generating step of generating a population of structural patterns, which are identified by a combination of a plurality of properties of the fastening part;
a section extracting step of extracting those sections which are disposed in a wet area of the aircraft where fuel or fuel vapor is present, from the sections of the fastening part including a leading end section located at the leading end of the fastening part and a base end section located at the base end of the fastening part, for each of the structural patterns of the population;
a group setting step of setting a group of the same predetermined properties of the structural patterns for each of the sections; and
a representative pattern selecting step of selecting a representative pattern representative of the group from the structural patterns belonging to the same group, and

the structural pattern narrowed down through the steps is determined as the test object.

The properties of the fastening part refer to various attributes, characteristics, and specifications of the fastening part, for example: the diameter, the material, with/without an insulation cap, the type of cap, and with/without bonding of the fastening member; the plate thickness of the members fastened with the fastening member; and with/without a seal between the members, etc.

The sections of the fastening part may include an intermediate section located between the leading end and the base end of the fastening part.

In addition, the sections of the fastening part may include one or more interface(s) in the thickness direction of the fastening part.

By the population generating step and the section extracting step of the present invention, each structural pattern is divided into the sections of the fastening member including the leading end section and the base end section.

Here, when looked at as a whole, the structural patterns are different in number of the members fastened with the fastening member, section located in the wet area, etc., but when the structural patterns are looked at on a section basis, the differences as a whole do not always appear and structural patterns of the same properties can be found.

Therefore, in the present invention, a group based on the properties is set for each section of the structural patterns (group setting step), and as will be described in detail later, a pattern of which the test can cover the other structural patterns is selected as a representative pattern from the structural patterns belonging to the same group.

In this way, it is possible to efficiently narrow down the structural pattern to be the object of the lightning protection adequacy verification test from the population including many structural patterns.

As the test is performed on only a part of the structural patterns which is determined as the test object and the lightning protection adequacy thereof is verified by the test, the lightning protection adequacy of all the structural patterns can be verified efficiently.

In the method for determining an object of an aircraft lightning protection adequacy test of the present invention, it is preferable that the maximum current of currents which are set for the structural patterns belonging to the group represented by the representative pattern is stored in the storing unit, and that the maximum current is used for the representative pattern as a current to be applied during the test.

If the maximum value of the current in the group is used during the lightning protection adequacy verification test, the test for the group can be finished at once.

Here, if the current set for the structural pattern is set for each section, it is preferable that the maximum current of each section in the group is stored in the storing unit and the maximum current of each section is applied during the test.

In the method for determining an object of an aircraft lightning protection adequacy test of the present invention, it is preferable that the following steps are performed by activating the calculation processing unit on the basis of a computer program: a group resetting step of setting a plurality of new groups which are identified by different combinations of the predetermined properties from those of the former groups; and a representative pattern reselecting step of selecting patterns representative of the new groups from the structural patterns belonging to the same new groups.

The structural patterns can be narrowed down to a smaller number of patterns by regrouping the structural patterns with a different combination of the properties and representing the new group by the pattern selected from the structural patterns belonging to the same new group.

The group setting step and the representative pattern selecting step can be performed yet again after the group resetting step and the representative pattern reselecting step.

A method for verifying aircraft lightning protection adequacy of the present invention includes the above-described method for determining an object of an aircraft lightning protection adequacy test, wherein the lightning protection adequacy of all the structural patterns included in the population is verified by performing the lightning protection adequacy test on the test object determined through the steps.

According to the present invention, it is possible to efficiently verify the lightning protection adequacy of numerous patterns of fastening parts of an aircraft.

### BRIEF DESCRIPTION OF THE DRAWINGS

FIG. 1 is a cross-sectional view showing a main wing of an aircraft according to an embodiment of the present invention;

FIGS. 2A to 2D are schematic views showing one example of the structure of a fastening part in an embodiment of the present invention;

FIGS. 3A to 3C are views illustrating various types of fastening members;

FIG. 4 is a schematic view (table) for illustrating how to narrow down structural patterns by section extraction and grouping on a section basis;

FIG. 5 is a schematic view continuing from the table of FIG. 4;

FIG. 6 is a flowchart showing one example of the procedure for determining an object of a lightning protection adequacy test;

FIG. 7 is a flowchart showing the procedure for selecting a representative structural pattern;

FIG. 8 is a flowchart showing an example of selection of a representative pattern; and

FIG. 9 is a flowchart showing an example of selection of a representative pattern by regrouping.

### DETAILED DESCRIPTION OF THE PREFERRED EMBODIMENTS

In the following, embodiments of the present invention will be described with reference to the accompanying drawings.

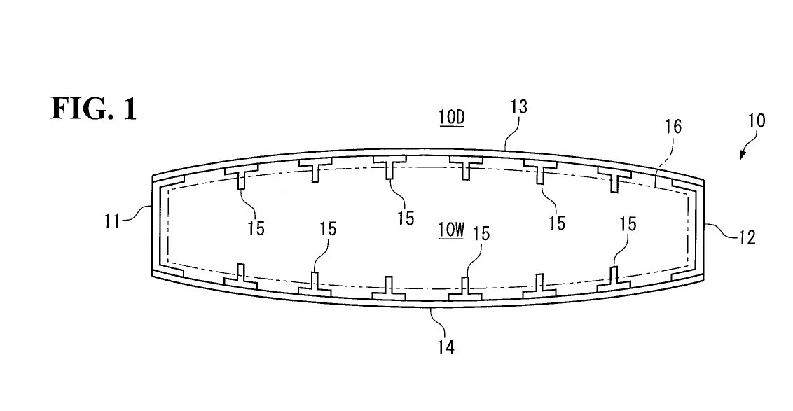

As shown in FIG. 1, a main wing 10 of an aircraft includes spars 11, 12 located on the leading edge and trailing edge, respectively; skins 13, 14 installed on the spars 11, 12 to form a box shape; a plurality of stringers 15 provided in the length direction of the main wing 10 on the rear side of each of the skins 13, 14; and a plurality of ribs 16 extending in the front-rear direction inside the main wing 10 and coupling the front and rear skins 13, 14.

For the above-described structural members 11 to 16 constituting the main wing 10, a material appropriately selected from metal such as aluminum, fiber reinforced plastics containing glass fiber (glass fiber reinforced plastics; GFRP), and fiber reinforced plastics containing carbon fiber (carbon fiber reinforced plastics; CFRP), and the like is used.

The main wing 10 also serves as a fuel tank, and fuel is stored inside the main wing 10 surrounded by the spars 11, 12 and the skins 13, 14. The inside of the main wing 10 is a wet area 10W which potentially comes into contact with fuel or fuel vapor. On the other hand, the outside of the main wing 10 is a dry area 10D which is free from the possibility of contact with fuel or fuel vapor.

The above-described structural members 11 to 16 constituting the main wing 10 and members which are added to these structural members 11 to 16 are fastened together with a fastening member such as a fastener. There are several tens of thousands of such points where the members are fastened with the fastening member.

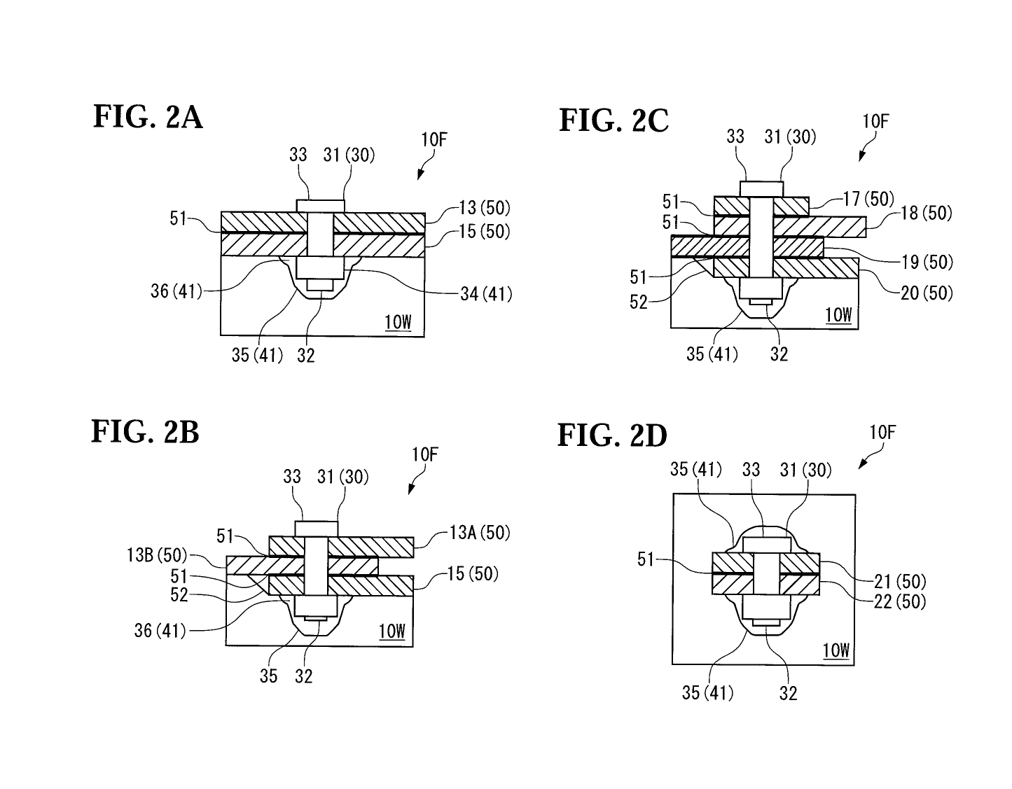

In the following, one examples of the structure at a fastening point (fastening part 10F) will be presented with reference to FIGS. 2A to 2D.

As shown in FIG. 2A, for example, the skin 13 and the stringer 15 are fastened together with a fastener 31 which penetrates the skin 13 and the flange of the stringer 15 from the front side of the skin 13. Many fasteners 31 are provided at intervals in the longitudinal direction of the stringer 15.

The skin 13 is constituted of a plurality of plate materials coupled in a planar direction. At the coupling part, the ends of the plate materials are lapped. Thus, as shown in FIG. 2B, three of a plate material 13A, a plate material 13B, and the stringer 15 are fastened with the fastener 31 penetrating them all.

In some cases, as shown in FIG. 2C, four members 17 to 20 lapped over one another are fastened with the fastener 31.

In the examples shown in FIGS. 2A to 2C, only a leading end 32 side of the fastener 31 and the plate materials that form mating surfaces on the leading end 32 side are disposed in the wet area 10W. The members forming a mating surface on the leading end 32 side are members 13B, 15 in FIG. 2B and members 19, 20 in FIG. 2C.

On the other hand, in the example shown in FIG. 2D, the entire fastener 31 including a head 33 side and members 21, 22 penetrated by the fastener 31 are all disposed in the wet area 10W. FIG. 2D corresponds to a case where, for example, the member 21 and member 22 provided on the side surface of the rib 16 are fastened with the fastener 31.

In this embodiment, the lightning protection adequacy of all the fastening parts 10F disposed in the wet area 10W is verified.

Various types of fastening members 30 including the fastener 31 are used for fastening the aircraft members 11 to 22.

The above-described fastener 31 is a fastening pin with no thread formed on it. The fastener 31 is used with a collar 34 to fasten the members. As necessary, a washer (not shown) is provided between the fastener 31 and the collar 34.

A cap 35 is provided so as to cover the leading end 32 side of the fastener 31. The cap 35 is formed of an insulating resin material and mounted on the leading end 32 side of the fastener 31. The cap 35 which blocks arcs, sparks, and melted scatters (hereinafter referred to as sparks, etc.) is provided so that, even when sparks, etc. occur around the fastener 31, these sparks, etc. do not fly out into the wet area 10W. An insulator 36 such as a sealant material is packed inside the cap 35 as necessary.

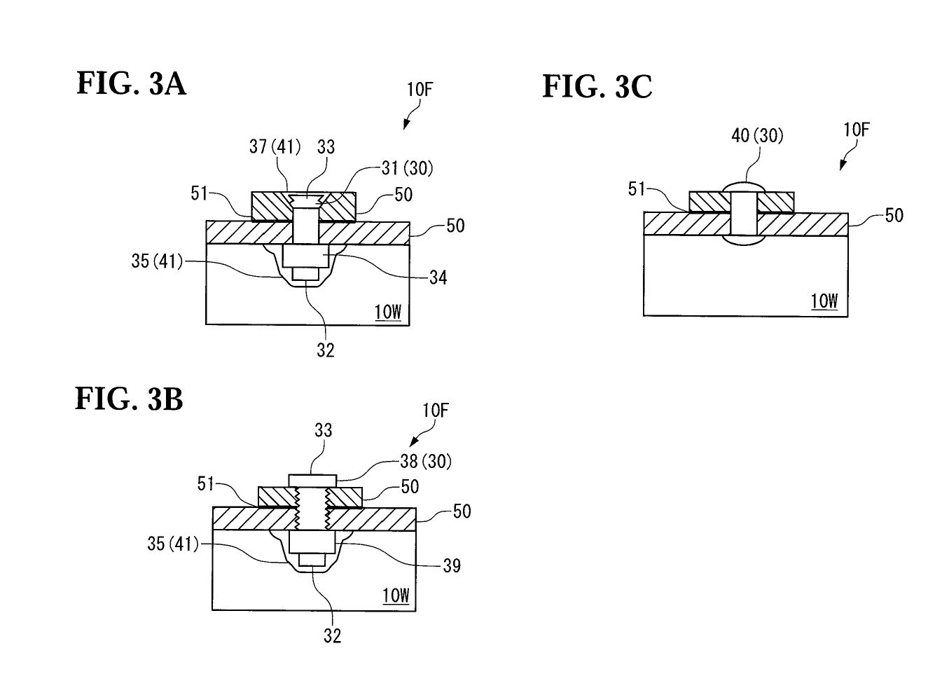

As shown in FIG. 3A, in some cases, a cap 37 formed of an insulating resin material is mounted on the head 33 of the fastener 31. The cap 37 insulates the head 33 of the fastener 31 to thereby suppress sparks, etc. occurring around the fastener 31 due to a high current flowing through the fastener 31 upon lightning strike on the main wing 10.

As shown in FIG. 3B, examples of the fastening member 30 include a fastening bolt 38 with a male thread formed on it. The fastening bolt 38 is used with a nut 39 with a mating female thread formed on it to fasten the members.

Examples of the fastening member 30 also include a rivet 40 shown in FIG. 3C.

When the main wing 10 is struck by lightning, the lightning current flows along the surface of the main wing 10, and also flows to the fastening member 30. In particular, when the skins 13, 14 are constituted of a fiber reinforced plastic, the current is likely to be concentrated in the fastening member 30 due to the difference in conductivity between the skins 13, 14 and the fastening member 30 which is typically metallic.

Sparks, etc. occurring in the wet area 10W through the fastening member 30 may lead to ignition.

The lightning current also diffuses from the skins 13, 14 and the spars 11, 12 constituting the surface of the main wing 10 through the fastening member 30 to the stringer 15 and the rib 16, etc. Therefore, the lightning current potentially flows through the fastener 31 which is entirely located inside the main wing 10 as shown in FIG. 2D, although it is lower than the current flow through the fastener 31 (FIGS. 2A to 2C) located on the front surface side of the main wing 10.

A specified current with a predetermined allowance relative to an expected lightning current is set for each fastening part 10F.

The fastening part 10F includes: the fastening member 30 selected from the fastener 31 (fastening pin), the fastening bolt 38, the rivet 40, etc.; accessory members 41 such as the collar 34, the nut 39, and the caps 35, 37 which accompany the fastening member 30 as necessary; and fastened members 50 such as the skin 13 and the stringer 15 which are fastened with the fastening member 30.

The fastening part 10F has various properties related to the fastening member 30, the accessory member 41, and the fastened member 50.

As will be described later, in this embodiment, the test object used for the lightning protection adequacy test is narrowed down with reference to the properties of the fastening part 10F.

As will be described later, the properties refer to, for example, the type of the fastening member 30 (bolt, pin, rivet, etc.); the diameter, the material, with/without the cap, the type of cap, and with/without bonding of the fastening member 30; the plate thickness of the fastened member 50; with/without a seal on the mating surface of the fastened members; and the material of the accessory member 41, etc., and the properties are defined in the light of various factors such as the rigidity and fastening strength required for the fastening part 10F, electrical conductivity, insulation performance, manufacturability, and cost.

For example, the fastening part 10F has the following properties related to the fastening member 30:
Type (fastening pin, fastening bolt, rivet)
Material (aluminum, titanium, etc.)
Type of material (among aluminums, for example, AMS-7050, AMS-7475, etc.)
Diameter
Surface roughness
With/without face bonding (electrical continuity), with/without fastener bonding
Types of collar and nut
With/without a cap, type of cap

Here, the properties with/without bonding, with/without a cap, and type of cap are explosion-proof measure properties which are directly linked to explosion proofing.

The fastening part 10F may include the above-mentioned specified current as a property.

In the above list, AMS stands for Aerospace Material Specification.

Face bonding means establishing electrical continuity between the surfaces of a planar material, while fastener bonding means establishing electrical continuity between the axial outer periphery of the fastener and the inner periphery of the hole.

The above-described properties are mere examples, and the tightness of fitting between the hole and the fastener may also be defined as a property.

The fastening part 10F, for example, has the following properties related to the fastened member 50:
Material (aluminum, GFRP, CFRP, etc.)
Plate thickness
With/without a seal, type of seal
With/without bonding
With/without shim

Here, the properties with/without a seal and with/without bonding are explosion-proof measure properties directly linked to explosion proofing.

The above-described properties related to the fastened member 50 are applied commonly to all the fastened members 50 of the spars 11, 12, the skins 13, 14, the stringer 15, the rib 16, and the other members 17 to 22, etc.

However, unique properties can also be defined for each type of the fastened members 50 such as the skin and the stringer.

As described above, the fastening part 10F includes the fastening member 30, the accessory member 41, and the fastened members 50, and has an assembly of the properties such as the examples given above related to these fastening member 30, accessory member 41, and fastened members 50.

There are as many as thousands of patterns of the fastening part 10F (hereinafter, structural patterns) which are identified by combinations of the properties of the fastening part 10F.

Performing the lightning protection adequacy test on all these structural patterns is difficult in terms of the workload, cost, and time of the test.

Here, the total number of the structural patterns depends on the number of properties used in dividing the fastening parts 10F according to the pattern.

The properties used for dividing the fastening parts 10F according to the pattern are defined in line with the following principles (a) to (c):

(a) The explosion-proof measure properties, such as with/without a seal, with/without a cap, type of cap, and with/without bonding, of course affect the lightning protection adequacy. Therefore, if there is no restriction on the number of structural patterns, it is preferable to select the structural pattern with a cap and the structural pattern with bonding, etc. respectively as the test objects in order to check that the lightning protection adequacy is provided.

Accordingly, the fastening parts 10F are divided according to the pattern using the explosion-proofing measure properties so as to include the structural patterns, which are classified by the explosion-proof measure properties, in the population of the structural patterns which are candidate test objects.

Then, the test objects are narrowed down by sorting the structural patterns by other properties, and if further narrowing down is necessary, a processing is performed such as selecting a structural pattern without a seal, for example, regarding the property of with/without a seal, which is more disadvantageous in terms of lightning protection adequacy.

If the fastening parts 10F are not divided according to the pattern using the explosion-proof measure properties, the explosion-proof measure properties would be buried in the structural patterns, so that the explosion-proof measure properties would become indistinguishable afterward. For this reason, too, the fastening parts 10F should be divided according to the pattern using the explosion-proof measure properties.

(b) It is difficult to theoretically prove that the properties such as the surface roughness and whether the material of the fastening member 30 is aluminum or titanium affect the lightning protection adequacy (it is not obvious that these properties do not affect the lightning protection adequacy). Therefore, in order to practically check the presence or absence of the lightning protection adequacy related to these properties by the test, the fastening parts 10F are divided according to the pattern using these properties. Then, the structural patterns are sorted by other properties to narrow them down.

(c) For the properties which clearly (obviously) affect the lightning protection adequacy, such as the diameter of the fastening member 30 and the plate thickness of the fastened member 50, the test of a structural pattern showing a more disadvantageous property can cover the test of a structural pattern showing a more advantageous property.

Therefore, for the diameter and the plate thickness, it is not absolutely necessary to divide the fastening parts 10F according to the pattern using these properties, and it is possible to form a population of structural patterns on the basis of the combination of properties given as examples in (a) and (b), and narrow down the structural patterns on the basis of the properties of (c).

Now, in this embodiment, the structural patterns are divided into a plurality of sections in order to efficiently narrow down the structural pattern to be the test object.

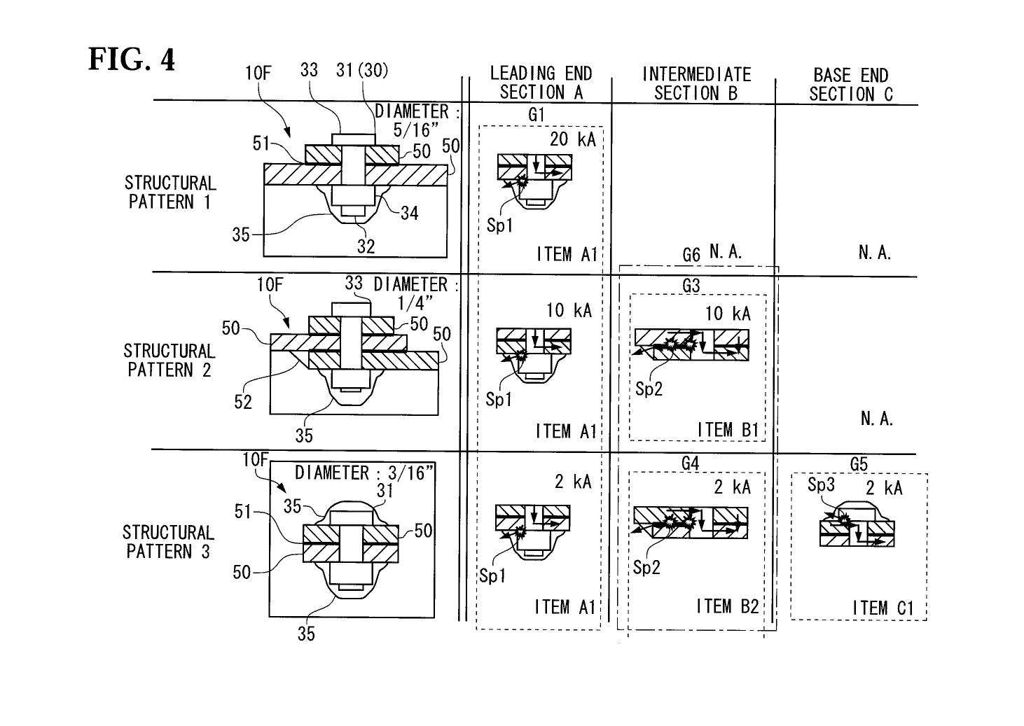

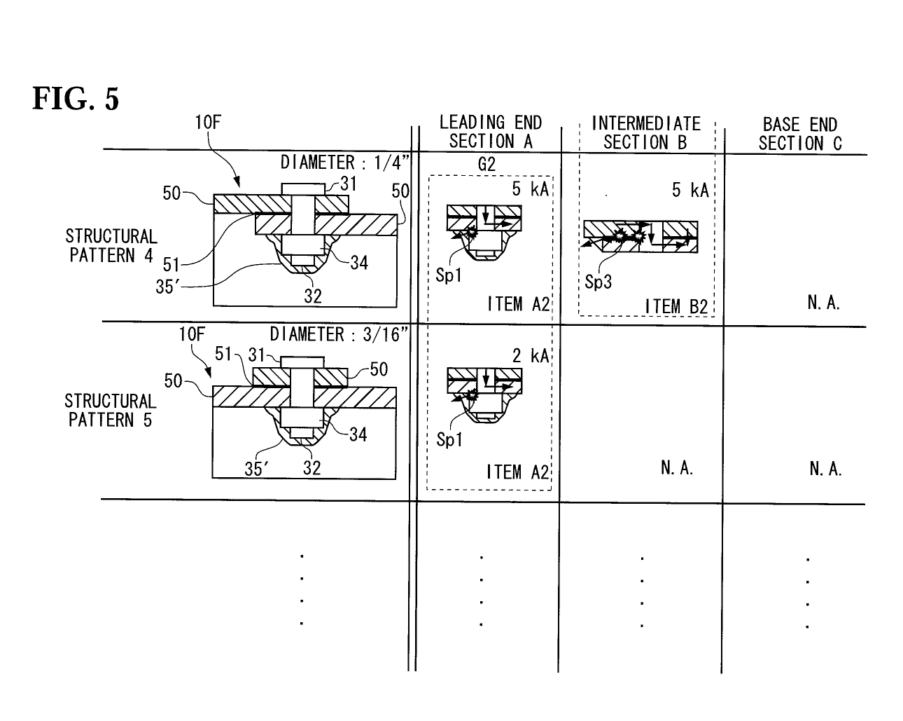

As shown in FIG. 4 and FIG. 5, the structural patterns are divided into a leading end section A located on the leading end 32 side of the fastening part 10F, a base end section C located on the head 33 side (base end side), and an intermediate section B which is a section where the fastened members 50 are lapped between the leading end 32 and the head 33.

The table shown in FIG. 4 and FIG. 5 has all the structural patterns (population) including a structural pattern 1, a structural pattern 2, and a structural pattern 3 as line elements arranged in the longitudinal direction, and sections A to C as the row elements arranged in the lateral direction.

When all the structural patterns are divided into sections as described above and only those sections that are disposed in the wet area 10W are extracted, for example, only the leading end section A is extracted as the section of the structural pattern 1. The intermediate section B and the base end section C of the structural pattern 1, which are not disposed in the wet area 10W, are not extracted.

As the sections of the structural pattern 2, the leading end section A and the intermediate section B are extracted. The base end section C of the structural pattern 2, which is not disposed in the wet area 10W, is not extracted.

As the section of the structural pattern 3, all of the leading end section A, the intermediate section B, and the base end section C are extracted.

For the structural pattern as shown in FIG. 2D, as with the structural pattern 2, the leading end section A and the intermediate section B disposed in the wet area 10W can be extracted.

In this embodiment, the structural patterns are divided into the sections using as a unit the interface along the thickness direction of the fastening part 10F.

As shown in FIG. 4 and FIG. 5, the leading end section A includes an interface which is a spark source (Sp1) between the collar 34 and the fastener 31. The intermediate section B includes an interface which is a spark source (Sp2) between the fastened member 50 and the fastened member 50. Then the base end section C includes an interface which is a spark source (Sp3) between the fastened member 50 and the head 33 of the fastener 31. A current flowing through each of these interfaces can be known. In this embodiment, the above-described specified current is set for each section.

The sections of the fastening part may include a plurality of interfaces.

Alternatively, instead of using the interface as a unit, for example, the structural patterns can also be divided into the sections by segmenting the fastening part 10F into the collar 34, the fastened member 50, the fastened member 50, and the head 33 of the fastener 31.

When the fastening part 10F is looked at as a whole, the structural patterns are different in number of fastened members 50, section disposed in the wet area 10W, etc. (see the left column of FIG. 4 and FIG. 5).

However, when the sections A to C are looked at section by section, the differences as a whole do not always appear and sections with the same predetermined properties can be found.

For example, the leading end sections A (items A1) of the structural patterns 1 to 3 form a group G1 having the same properties in terms of the type of fastening member 30 (fastening pin), with/without the cap 35 (with), the type of cap (same), and with/without the seal 51 (with).

The above-described structural patterns 1 to 3 are extracted from the population as the structural patterns forming the group G1. It is assumed that the group G1 is not set for other structural patterns than the structural patterns 1 to 3.

As will be described later, when the structural patterns 1 to 3 belonging to the group G1 are compared on the leading end section A, the structural pattern 3 is the one having the worst item of the most disadvantageous property in terms of lightning protection adequacy.

Thus, if a structural pattern (structural pattern 3) is the most disadvantageous one in terms of lightning protection adequacy in the group, the lightning protection adequacy test performed on this structural pattern can substitute the lightning protection adequacy tests to be performed on the other structural patterns (structural patterns 1, 2). That is, since presence or absence of the lightning protection adequacy of the structural patterns 1, 2 can be checked by performing the test on the structural pattern 3, the test on the structural pattern 3 can cover the tests for the structural patterns 1, 2. Thus, the group G1 is represented by the structural pattern 3 and the structural patterns 1, 2 can be excluded from the test object.

If the structural patterns in the group are equivalent in lightning protection adequacy, any structural pattern may be selected as the test object, and an arbitrary one structural pattern can represent the group.

Thus, the structural pattern 3 representing the structural patterns 1 to 3 can be used as the test object to perform the lightning protection adequacy test.

The lightning protection adequacy of all the structural patterns 1 to 3 can be verified by checking that ignition such as sparks is not observed from the leading end section A, the intermediate section B, and the base end section C.

Also for the structural patterns other than the structural patterns 1 to 3, as described above, a group of the same predetermined properties is found for each of the sections A, B, and C, and a structural pattern which includes other structural patterns in the group can represent the group.

In this way, the structural pattern to be the test object is narrowed down.

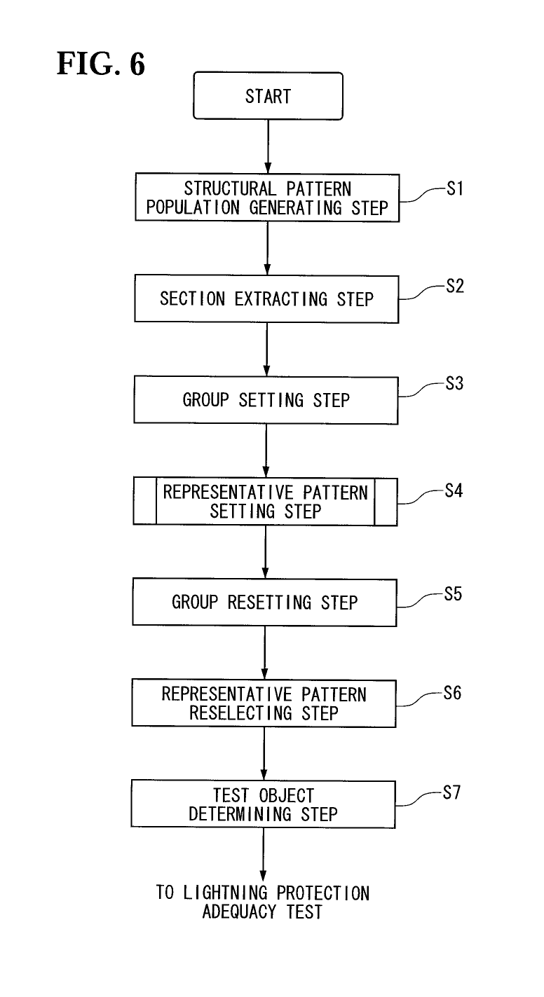

Next, one example of the procedure for determining the object of the lightning protection adequacy test will be described with reference to FIG. 6.

The following steps are performed by activating a calculation unit on the basis of a computer program using a computer having a calculation processing unit which performs calculations and a storing unit which stores information used for the calculations.

First, a population of structural patterns which are disposed at least partly in the wet area 10W is formed from all the possible combinations of properties by which the explosion-proof measure properties and the lightning protection adequacy are not obviously unaffected (structural pattern population generating step S1).

Next, for each structural pattern, the leading end section A, the intermediate section B, and the base end section C disposed in the wet area 10W are extracted (section extracting step S2).

Thus, the table data shown in FIG. 4 and FIG. 5 is created.

In the following, the structural pattern to be the test object is narrowed down by comparing the items included in the table data.

First, a group of the same predetermined properties of the structural patterns is set for each section (group setting step S3).

Here, a group of the same properties in terms of the type of the fastening member 30, with/without a cap and the type of cap, and with/without a seal is set.

For example, items of the leading end section A having a fastening pin as the fastening member 30, with the cap 35, with the same type of the cap 35, and with the seal 51 are set as a first group. On the other hand, items of the leading end section A, which are different from the first group only in type of the cap, having a fastening pin as the fastening member 30, with another type of cap 35, and with the seal 51 are set as a second group.

Many groups are set for each of the sections A to C.

For example, in the structural patterns 1 to 5 (FIG. 4 and FIG. 5), the group G1 and the group G2 are set for the leading end section A, the group G3 and group G4 are set for the intermediate section B, and the group G5 is set for the base end section C.

Here, naturally, no group is set for non-existent sections (indicated by N.A. in FIG. 4 and FIG. 5).

It is also acceptable that two or more groups are set for an identical section of an identical structural pattern at the same time. Also in this case, a representative pattern can be selected in the same manner as will be described below.

Next, a representative pattern representing the group is selected from the structural patterns belonging to the same group (representative pattern selecting step S4).

The criteria for representing the group (summarizing the structural patterns) is, as described above, whether the structural pattern is the most disadvantageous one in terms of lightning protection adequacy, and the structural pattern which is the most disadvantageous one in terms of lightning protection adequacy is selected as a candidate representative of the group. Then, the selection results of the candidate representatives of the groups are summarized to select a representative pattern.

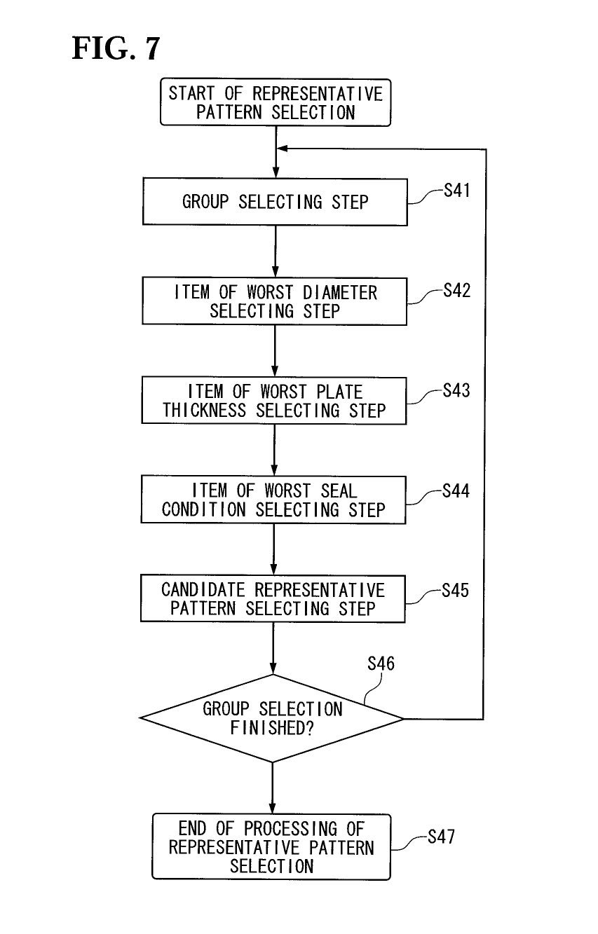

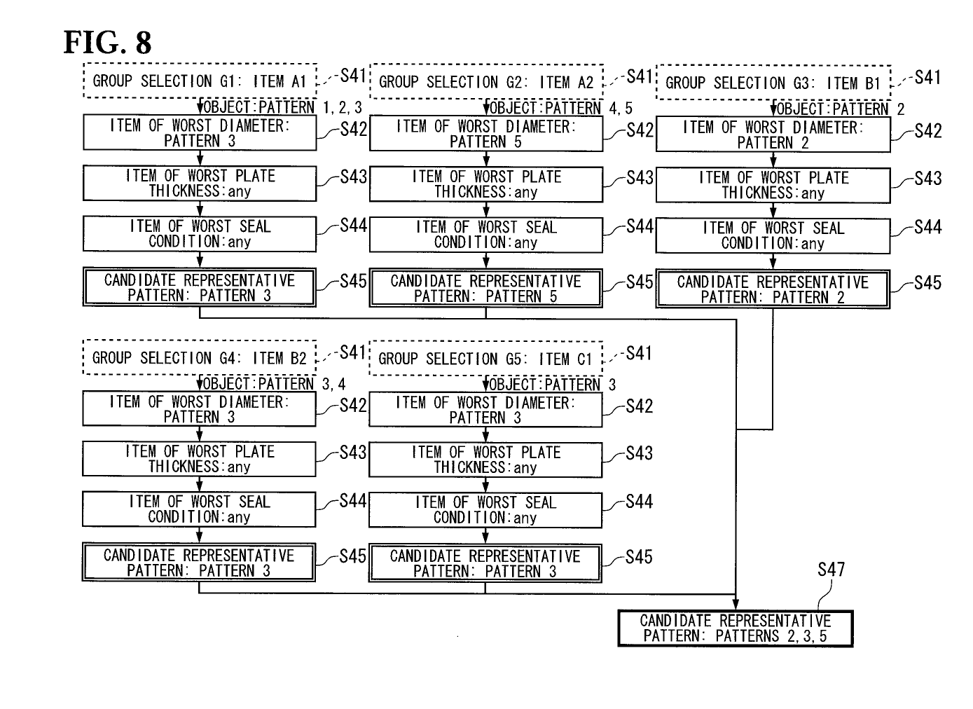

To take the structural patterns 1 to 5 as an example, the representative pattern is selected by determining, sequentially for each group, whether the structural pattern is most disadvantageous (worst) in terms of lightning protection adequacy (FIG. 7). FIG. 8 shows the development of the processing for each group.

First, the group G1 set for the leading end section A is selected (group selecting step S41).

Next, the worst item of the group is selected and thereby the flow proceeds to a processing of selecting a candidate representative.

The following steps S42 to S45 are performed on each group with reference to the properties related to the diameter, the plate thickness, and the seal.

Here, the group G1 is selected for the structural patterns 1 to 3. Therefore, the item of the group G1 which has the smallest diameter of the fastener 31 and is worst in terms of lightning protection adequacy is selected (item of worst diameter selecting step S42).

Subsequently, the item of the group G1 which has the smallest plate thickness of the fastened member 50 and is worst in terms of lightning protection adequacy is selected (item of worst plate thickness selecting step S43).

Further, the item of the group G1 which has the worst seal condition is selected (item of worst seal condition selecting step S44).

Of the structural patterns 1 to 3, the structural pattern 3 has the smallest diameter of the fastener 31. Therefore, the item A1 of the structural pattern 3 is selected as the item of the worst diameter.

On the other hand, the structural patterns 1 to 3 are equal in plate thickness of the fastened member 50, and having the same seal 51, these structural patterns are also equal in seal conditions. Therefore, no worst item is selected related to these plate thickness and seal condition. The worst items of these plate thickness and seal condition should follow the worst item selection result of other elements (here, the diameter of the fastener 31), and a flag, etc. to this effect (indicated by “any” in FIG. 8) is stored.

The order of the above-described steps S42 to 44 of selecting the worst items in terms of diameter, plate thickness, and seal is arbitrary.

By the processing so far, the structural pattern 3 is selected as a candidate representative pattern of the group G1 (candidate representative pattern selecting step S45).

In this candidate representative pattern selecting step S45, it is preferable that the maximum current in the same group as that of the candidate representative pattern is retained in the storing unit. In the example of the group G1, the value 20 kA set as the specified current for the leading end section A of the structural pattern 1 is retained in the storing unit.

Further, other groups G2, G3, G4, and G5 are sequentially selected, and the above-described steps S42 to S45 are repeated until the processing of the final group is finished (Yes in step S46).

Then, as shown in FIG. 8, the structural pattern 3, the structural pattern 5, the structural pattern 2, the structural pattern 3, and the structural pattern 3 are selected as the result of the candidate representative pattern selection of the groups G1 to G5, respectively.

When these candidate representative patterns are summarized, the structural pattern 2, the structural pattern 3, and the structural pattern 5 are selected as representative patterns for the structural patterns 1 to 5 (representative pattern selecting step S47).

According to the above processing, a group is set for the sections present in the wet area 10W of the structural patterns, and the worst item in the group is selected. The test object can be narrowed down by such processing, because, when there is one structural pattern which can substitute the lightning protection adequacy test of another pattern, the another pattern can be excluded from the test object and represented by the one structural pattern.

As shown in the table of FIG. 4 and FIG. 5 and the candidate representative pattern selection results of FIG. 8, even when the fastening parts 10F as a whole are different in configuration, they can be grouped together on the basis of the same predetermined properties among the sections of other structural patterns.

Then, if the leading end section A of the structural pattern 1 is applied to the leading end section A of the structural pattern 3 of the same group G1, the structural pattern 1, which has no other sections, can be excluded from the test object.

For the structural pattern 4, the leading end section A is applied to the leading end section A of the structural pattern 5 of the same group G2 and the intermediate section B is applied to the intermediate section B of the structural pattern 3 of the same group G4, so that the structural pattern 4, which has no other sections, can be excluded from the test object.

Thus, by distributing the sections of one structural pattern to other structural patterns, the test object can be efficiently narrowed down.

A candidate representative is selected in the same way as described above by selecting the worst item of the group for all the groups set for the structural patterns, and a representative pattern is selected on the basis of the candidate representative selection results.

Here, a comparison of the items in a group sometimes finds that three items, the item of the worst diameter, the item of the worst plate thickness, and the item of the worst seal condition, do not coincide. In that case, the processing of representative pattern selection can be finished for the structural patterns related to the group. Alternatively, the processing of representative pattern selection can be continued by weighting the three items and selecting the worst item in terms of the most important property.

In some cases, the items of a group are equal in all of the diameter, the plate thickness, and the seal conditions and there is no worst item. In that case, one of the items of the group can be selected arbitrarily.

When a representative pattern is selected by the above-described representative pattern selecting step S4, the structural patterns have been narrowed down compared to the number of the structural patterns included in the population of the structural patterns.

In this embodiment, for further narrowing down, a new group is set for the existing structural patterns regardless of the explosion-proof measure properties (group resetting step S5), and a representative pattern is selected from the structural patterns belonging to the new group (representative pattern reselecting step S6).

In step S5, for example, a group is reset with the property of the seal excluded from the properties used as a reference in the above-described group setting step S3.

Here, it is not necessary to exclude all the plurality of explosion-proof measure properties such as with/without a cap, the type of cap, with/without a seal, and with/without bonding from the properties used for resetting the group, and it is only necessary to reset the group with a part of the explosion-proof measure properties (e.g., the property of the seal) excluded.

Then, the same processing as the above-described representative pattern selecting step S4 is performed within the reset group (new group). It is assumed that by this processing, for example, the group G6 is set for the item B2 of the structural pattern 2 and the item B2 of the structural pattern 3 as shown in FIG. 4 and FIG. 5. Since the structural pattern 4 is excluded from the test object, it is not considered as the object of the group G6.

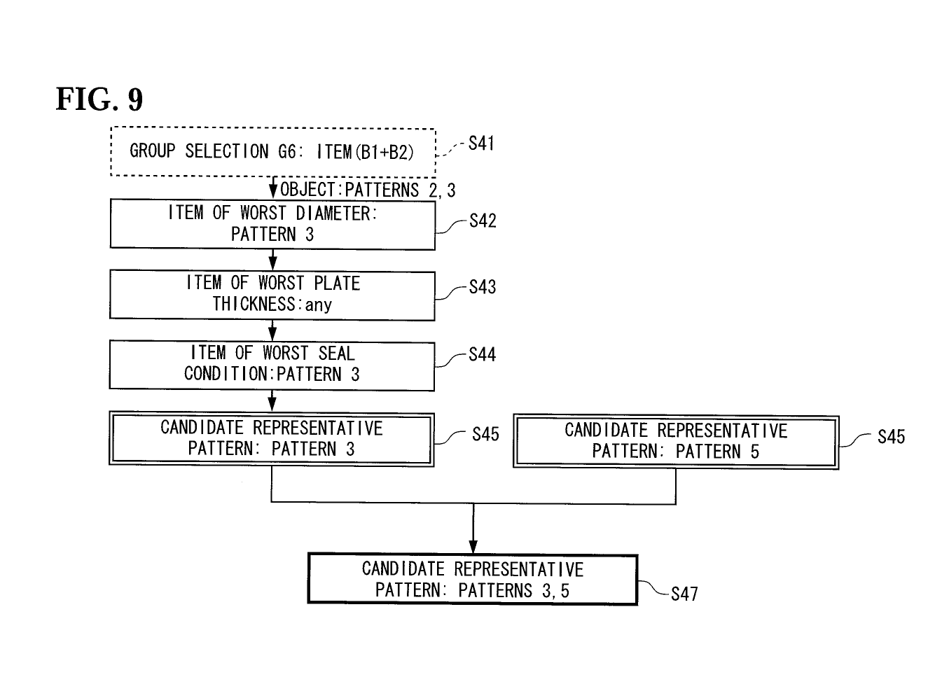

In the above case, as shown in FIG. 9, the structural pattern 3 is selected as the item of the worst diameter while the item of the worst plate thickness is not selected, and the structural pattern 3 without a fillet seal 52 is selected as the item of the worst seal condition.

Then, for the structural patterns 1 to 5, only the structural patterns 3, 5 of the structural patterns 2, 3, and 5, which are selected as the test objects by the above-described representative pattern selecting step S4, are left as the test objects.

Through these steps S1 to S7, the structural patterns are narrowed down, for example, to about several tens of patterns. These structural patterns are determined as the test objects (step S7).

Once the test objects are determined, a test piece including the structural pattern of the test object is produced, and the lightning protection adequacy test is performed. Several test pieces including a single or a plurality of structural pattern(s) are produced for each test object.

During the test, the maximum specified current for each section is applied to the representative patterns with reference to the data on the current retained in the storing unit for each section of the representative patterns which are the test objects. For example, for the structural pattern 3, a current of 20 kA which is the maximum specified current of the group represented by the structural pattern 3 is applied during the test.

When the test piece is struck by lightning and no ignition such as sparks due to electric discharge is observed, the lightning protection adequacy of the structural patterns included in the test piece is verified. The lightning protection adequacy of all the structural patterns can be verified by verifying the lightning protection adequacy by the test on the small number of structural patterns serving as the test objects.

In the lightning protection adequacy test, ignition such as sparks can be observed. This can happen in such cases as when a higher specified current than the current set to other structural patterns represented by the structural pattern is applied to the representative pattern selected as the test object, or when the structural pattern having no necessary explosion-proof measure properties against the applied current is selected as a representative pattern.

In some cases it is possible to determine in advance, from the relation of the properties of the representative pattern selected as the test object and the applied current, that there is a great possibility that spark, etc. fly when the test is performed.

In that case, for example, the following processing can be performed.

First, the largest specified current next to the maximum specified current having been selected to be used for the test is reselected, and the test is performed again (current resetting step).

If ignition is still observed and the lightning protection adequacy cannot be verified yet, the structural patterns having been selected by setting the group regardless of the explosion-proof measure properties (steps S5, S6) are removed from the representative, and the structural patterns represented by these representative patterns are recovered as the test objects (representative removing and recovering step).

If the test can be successfully performed (no ignition is observed) by performing the above-described current resetting step and the representative removing and recovering step, it is not necessary to remove the representatives selected in step S4.

According to this embodiment, as described above, it is possible to form a population of structural patterns on the basis of a combination of properties, and to compare the properties of the items by extracting the sections of the structural patterns. Then, it is possible to efficiently narrow down the test object and verify the lightning protection adequacy of an aircraft by representing the group by a structural pattern which includes other structural patterns in the group set for each section.

In the above-described procedure for determining the test object, the structural patterns are narrowed down on a step-by-step basis by repeating the group setting and the representative pattern selection. However, the narrowing down may be finished at a point when the structural patterns to be the test objects are narrowed down to a predetermined number.

The result of narrowing down varies depending on the properties used for dividing the fastening parts 10F according to the pattern, the properties used for grouping, and the properties used for selection of the worst item. Which property to use in each step of the test object determination procedure can be determined through prior trial calculations, etc.

In the above embodiment, there is one population of the structural patterns, and the group is first set for all the structural patterns. However, the population of the structural patterns may be divided before setting a group. For example, depending on the member for which the fastening part 10F is provided, a plurality of populations such as a structural pattern of the fastening part 10F fastening the skins, the structural pattern of the fastening part 10F fastening the skin and the rib, the structural pattern of the fastening part 10F fastening the skin and the stringer, or the structural pattern of the fastening part 10F fastening the spar and skin are formed. Then, since the structural patterns having similar objects to be fastened have many properties in common, there is a greater chance that the structural pattern which can be substituted by the other structural pattern can be excluded from the test object. That is, the hit rate in narrowing down can be increased, so that the structural patterns can be narrowed down more efficiently.

Other than these examples, the configurations presented in the above-described embodiments may be selected or appropriately changed into other configurations within the scope of the present invention.

What is claimed is:

1. A method for determining an object of a test for verifying lightning protection adequacy of a fastening part which is a structure at a point where members of an aircraft are fastened together with a fastening member, wherein
the following steps are performed by using a computer having a calculation processing unit which performs calculations and a storing unit which stores information used for the calculations and activating the calculation processing unit on the basis of a computer program:
a population generating step of generating a population of structural patterns, which are identified by a combination of a plurality of properties of the fastening part;
a section extracting step of extracting those sections which are disposed in a wet area of the aircraft where fuel or fuel vapor is present, from the sections of the fastening part including a leading end section located at the leading end of the fastening part and a base end section located at the base end of the fastening part, for each of the structural patterns of the population;
a group setting step of setting a group of the same predetermined properties of the structural patterns for each of the sections; and
a representative pattern selecting step of selecting a representative pattern representative of the group from the structural patterns belonging to the same group, and
the structural pattern narrowed down through the steps is determined as the test object.

2. The method for determining an object of an aircraft lightning protection adequacy test according to claim 1, wherein
the maximum current of currents which are set for the structural patterns belonging to the group represented by the representative pattern is stored in the storing unit, and
the maximum current is used for the representative pattern as a current to be applied during the test.

3. The method for determining an object of an aircraft lightning protection adequacy test according to claim 1, wherein
the following steps are performed by activating the calculation processing unit on the basis of the computer program:
a group resetting step of setting a plurality of new groups which are identified by different combinations of the predetermined properties from those of the former groups; and
a representative pattern reselecting step of selecting patterns representative of the new groups from the structural patterns belonging to the same new groups.

4. The method for determining an object of an aircraft lightning protection adequacy test according to claim 1, wherein the sections of the fastening part include an intermediate section which is located between the leading end and the base end of the fastening part.

5. The method for determining an object of an aircraft lightning protection adequacy test according to claim 1, wherein the sections of the fastening part include one or more interface(s) in the thickness direction of the fastening part.

6. A method for verifying aircraft lightning protection adequacy including the method for determining an object of an aircraft lightning protection adequacy test according to claim 1, wherein the lightning protection adequacy of all the structural patterns included in the population is verified by performing the lightning protection adequacy test on the test object determined through the steps.
